(19) United States
(12) Patent Application Publication
(10) Pub. No.: US 2014/0085522 A1
(43) Pub. Date: Mar. 27, 2014

(54) SOLID-STATE IMAGING DEVICE, CAMERA MODULE, AND IMAGING METHOD

(71) Applicant: KABUSHIKI KAISHA TOSHIBA, Tokyo (JP)

(72) Inventors: Yumi YATSUNAMI, Kanagawa (JP); Tatsuji Ashitani, Kanagawa (JP); Yukiyasu Tatsuzawa, Kanagawa (JP); Takahiko Mihara, Kanagawa (JP)

(73) Assignee: Kabushiki Kaisha Toshiba, Tokyo (JP)

(21) Appl. No.: 13/756,820

(22) Filed: Feb. 1, 2013

(30) Foreign Application Priority Data
Sep. 24, 2012 (JP) 2012-209668

(51) Int. Cl. H01L 27/146

(52) U.S. Cl. CPC H01L 27/14625
USPC 348/308; 250/208.1

(57) ABSTRACT

According to one embodiment, a solid-state imaging device includes a pixel array and a row selection circuit. The pixel array outputs a signal for each cell. The cell includes a plurality of pixels arranged in parallel in a column direction. The cells are arranged such that positions in the column direction of a first cell and a second cell are staggered. The first cell includes a blue pixel and a green pixel. The second cell includes a green pixel and a red pixel. In a binning process in the column direction, the row selection circuit selects rows including the green pixel in the first cell at the same time for the first cell. In the binning process in the column direction, the row selection circuit selects rows including the green pixel in the second cell at the same time for the second cell.

### CROSS-REFERENCE TO RELATED APPLICATIONS

This application is based upon and claims the benefit of priority from Japanese Patent Application No. 2012-209668, filed on Sep. 24, 2012; the entire contents of all of which are incorporated herein by reference.

### FIELD

Embodiments described herein relate generally to a solid-state imaging device, a camera module, and an imaging method.

### BACKGROUND

Recently, there are solid-state imaging devices that perform the binning process as a measure against the increase in the amount of data with the increase in resolution. The solid-state imaging device can suppress the amount of data by treating data from a plurality of pixels as one piece of data by the binning process.

A complementary metal oxide semiconductor (CMOS) image sensor is known that adopts a structure in which one output circuit is connected to a predetermined number of photodiodes. With this structure, a predetermined number of pixels constitute one cell and a signal is output from each cell. A plurality of pixels is treated as one cell, therefore, the solid-state imaging device can be expected to increase the saturated charge amount, improve the sensitivity, and reduce the random noise.

For example, with the configuration in which a predetermined number of pixels arranged in parallel in a column direction are treated as one cell, circuits can be highly integrated in the column direction by arranging an output circuit for every predetermined number of pixels in the column direction. Furthermore, in the solid-state imaging device, circuits can be highly integrated not only in the column direction but also in the row direction by making the position of a cell in the column direction different between columns adjacent to each other. The configuration of the solid-state imaging device can be advantageous in terms of the layout by highly integrating circuits both in the column direction and the row direction.

The solid-state imaging device can perform the binning process of reducing the amount of data to half in the column direction by reading charge of two pixels of the same color in the column direction at the same time. In the solid-state imaging device in which the positions of cells in the column direction are staggered every column, when such a binning process is performed, there are a color component for which charge for two pixels is summed in one cell and is read and a color component for which charge read from two cells each for one pixel is averaged is read. In the solid-state imaging device, averaging charge read from two cells may deteriorate the signal-to-noise ratio (SNR).

### BRIEF DESCRIPTION OF THE DRAWINGS

FIG. 1 is a block diagram illustrating a schematic configuration of a solid-state imaging device according to the first embodiment;

FIG. 2 is a block diagram illustrating a schematic configuration of a digital camera including the solid-state imaging device shown in FIG. 1;

FIG. 3 is a diagram illustrating a circuit configuration example of a cell;

FIG. 4 is a diagram illustrating an arrangement of a color filter;

FIG. 5 is a diagram explaining the order of selecting a row, from which signal charge is read, by a vertical shift register in the binning process in the column direction;

FIG. 6 is a diagram explaining a spatial arrangement of signal values obtained by the binning process when a row is selected in the order shown in FIG. 5;

FIG. 7 is a diagram explaining the order of selecting a row in the binning process in a comparison example of the first embodiment;

FIG. 8 is a diagram explaining a spatial arrangement of signal values obtained by the binning process when a row is selected in the order shown in FIG. 7; and

FIG. 9 is a diagram explaining the binning process by a solid-state imaging device according to the second embodiment.

### DETAILED DESCRIPTION

In general, according to one embodiment, a solid-state imaging device includes a pixel array, a color filter, and a row selection circuit. Pixels are arranged in an array in a row direction and a column direction in the pixel array. The pixel array outputs a signal for each cell. The cell includes a plurality of pixels arranged in parallel in the column direction. The color filter selectively causes colored light detected in a pixel to pass therethrough for each pixel. The row selection circuit selects a row of a pixel from which signal charge is read in the pixel array. A red color filter, a green color filter, and a blue color filter are arranged in the color filter. The red color filter causes red light to pass therethrough. The green color filter causes green light to pass therethrough. The blue color filter causes blue light to pass therethrough. Cells are arranged such that positions in the column direction of a first cell and a second cell are staggered. The first cell includes a blue pixel and a green pixel. The second cell includes a green pixel and a red pixel. The blue pixel is a pixel corresponding to the blue color filter. The green pixel is a pixel corresponding to the green color filter. The red pixel is a pixel corresponding to the red color filter. In a binning process in the column direction, the row selection circuit selects rows including the green pixel in the first cell at a same time for the first cell. In a binning process in the column direction, the row selection circuit selects rows including the green pixel in the second cell at a same time for the second cell.

Exemplary embodiments of a solid-state imaging device, a camera module, and an imaging method will be explained below in detail with reference to the accompanying drawings.

The present invention is not limited to the following embodiments.

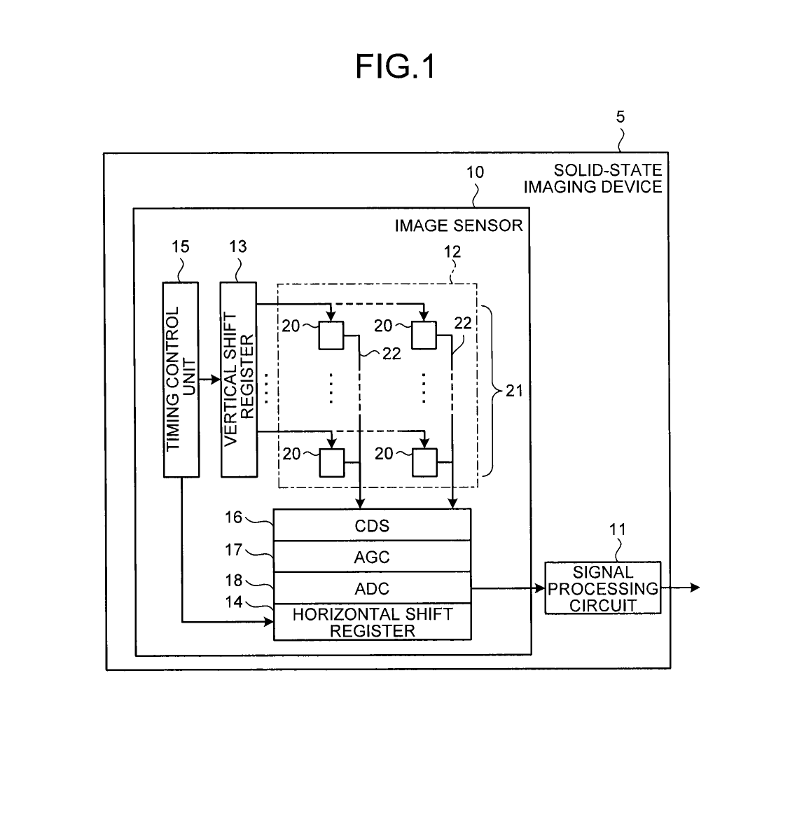

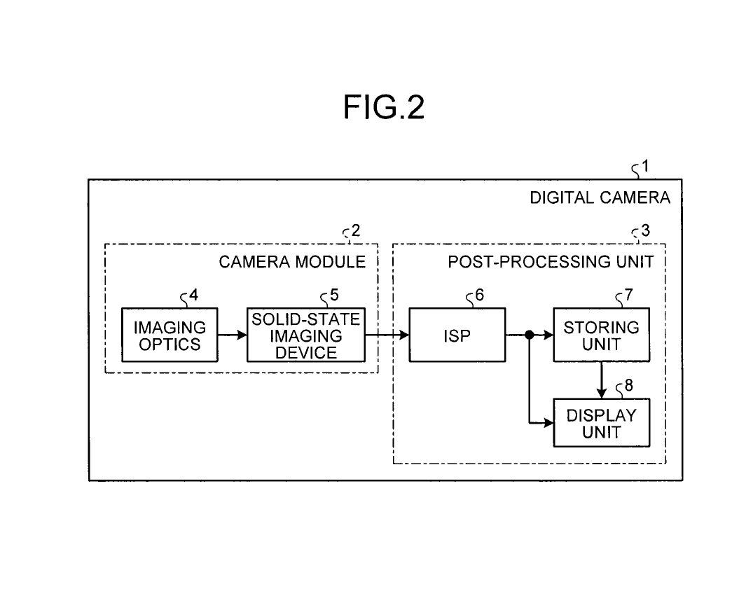

FIG. 1 is a block diagram illustrating a schematic configuration of a solid-state imaging device according to the first embodiment. FIG. 2 is a block diagram illustrating a schematic configuration of a digital camera including the solid-state imaging device shown in FIG. 1.

A digital camera 1 includes a camera module 2 and a post-processing unit 3. The camera module 2 includes an imaging optics 4 and a solid-state imaging device 5. The post-processing unit 3 includes an image signal processor (ISP) 6, a storing unit 7, and a display unit 8. For example, the camera module 2 is applied to electronics, such as a camera-equipped mobile terminal, in addition to the digital camera 1.

The imaging optics 4 captures light from an object and forms an object image. The solid-state imaging device 5 captures the object image. The ISP 6 performs the signal process on an image signal obtained by the imaging in the solid-state imaging device 5. The storing unit 7 stores an image subjected to the signal process in the ISP 6. The storing unit 7 outputs an image signal to the display unit 8 in accordance with a user operation or the like. The display unit 8 displays an image in accordance with the image signal input from the ISP 6 or the storing unit 7. The display unit 8 is, for example, a liquid crystal display.

The solid-state imaging device 5 includes an image sensor 10 and a signal processing circuit 11. The image sensor 10 is, for example, a complementary metal oxide semiconductor (CMOS) image sensor. The image sensor 10 includes a vertical shift register 13, a horizontal shift register 14, a timing control unit 15, a correlated double sampling unit (CDS) 16, an automatic gain control unit (AGC) 17, an analog-to-digital converter (ADC) 18, and a pixel array 21.

The pixel array 21 is provided in an imaging region 12 of the image sensor 10. The pixel array 21 is composed of a plurality of pixels arranged in an array in the horizontal direction (row direction) and the vertical direction (column direction). Each pixel includes a photodiode that is a photoelectric conversion element. A cell 20 includes four pixels (not shown) arranged in parallel in the column direction.

The timing control unit 15 supplies a timing signal instructing the timing of reading a signal from each pixel of the pixel array 21 to the vertical shift register 13 and the horizontal shift register 14. The vertical shift register 13 selects pixels in the pixel array 21 for each row in accordance with the timing signal from the timing control unit 15. The vertical shift register 13 outputs a read signal to each pixel of the selected row.

Pixels to which the read signal is input from the vertical shift register 13 output signal charge accumulated in accordance with the incident light intensity. The pixel array 21 sets the signal charge output from the pixels as a signal for each cell 20. The pixel array 21 outputs a signal for each cell 20. The pixel array 21 outputs a signal from the cell 20 to the CDS 16 via vertical signal lines 22. The vertical shift register 13 functions as a row selection circuit that selects a row from which signal charge is read in the pixel array 21.

The CDS 16 performs a correlated double sampling process on signals from the pixel array 21 for reducing a fixed pattern noise. The AGC 17 amplifies the signals subjected to the correlated double sampling process in the CDS 16. The ADC 18 converts the signals subjected to the amplification in the AGC 17 from an analog form to a digital form.

The horizontal shift register 14 sequentially reads the signals converted into a digital form in the ADC 18 in accordance with a timing signal from the timing control unit 15. The signal processing circuit 11 performs various signal processes on the digital image signals read by the horizontal shift register 14.

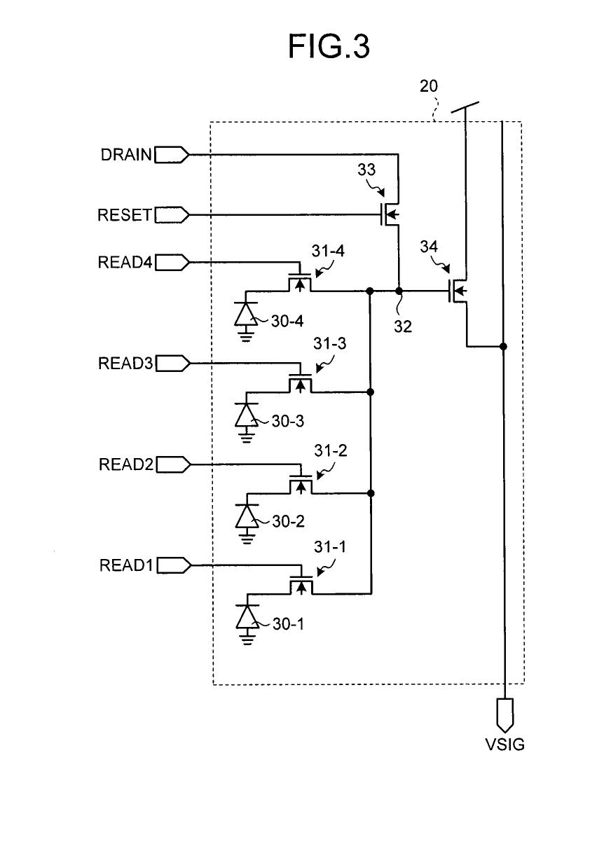

FIG. 3 is a diagram illustrating a circuit configuration example of the cell. The cell 20 includes four photodiodes (PD) 30-1, 30-2, 30-3, and 30-4, four transfer transistors 31-1, 31-2, 31-3, and 31-4, a floating diffusion (FD) 32, a reset transistor 33, and an amplifying transistor 34.

The PDs 30-1, 30-2, 30-3, and 30-4, which are photoelectric conversion elements, generate signal charge in accordance with the incident light intensity. The transfer transistor 31-1 transfers signal charge from the PD 30-1 to the FD 32 in accordance with a read signal (READ1) from the vertical shift register 13. The transfer transistor 31-2 transfers signal charge from the PD 30-2 to the FD 32 in accordance with a read signal (READ2) from the vertical shift register 13. The transfer transistor 31-3 transfers signal charge from the PD 30-3 to the FD 32 in accordance with a read signal (READ3) from the vertical shift register 13. The transfer transistor 31-4 transfers signal charge from the PD 30-4 to the FD 32 in accordance with a read signal (READ4) from the vertical shift register 13.

The FD 32 converts the signal charge transferred by the transfer transistors 31-1, 31-2, 31-3, and 31-4 to a potential. The amplifying transistor 34 amplifies the potential change of the FD 32 to obtain an image signal (VSIG). The reset transistor 33 drains (DRAIN) charge of the FD 32 in accordance with a reset signal (RESET) from the vertical shift register 13 and resets the potential of the FD 32 to a certain level. The configuration of the cell 20 is not limited to that shown in FIG. 3 and may be appropriately changed.

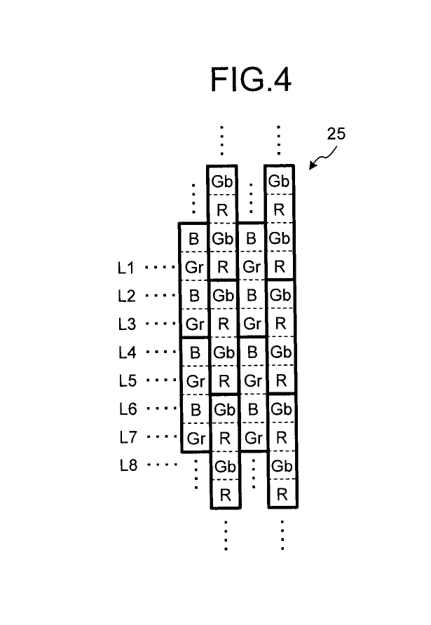

FIG. 4 is a diagram illustrating an arrangement of a color filter. A color filter 25 selectively causes colored light detected in a pixel to pass therethrough for each pixel. In the color filter 25, color filters of each of the colors, i.e., red (R), green (G), and blue (B), are arranged in a Bayer array. The R color filter causes R light to pass therethrough. The G color filter causes G light to pass therethrough. The B color filter causes B light to pass therethrough.

R pixels corresponding to the R color filters, Gr pixels and Gb pixels corresponding to the G color filters, and B pixels corresponding to the B color filters are arranged in a Bayer array in the pixel array 21 in a similar manner to the color filter 25.

An R pixel detects R light passed through the R color filter. A B pixel detects B light passed through the B color filter. A Gr pixel and a Gb pixel detect G light passed through the G color filters. Gr pixels are arranged in parallel with R pixels in the row direction. Gb pixels are arranged in parallel with B pixels in the row direction.

The cell 20 including two B pixels and two Gr pixels is defined as a first cell and the cell 20 including two Gb pixels and two R pixels is defined as a second cell. The first cell and the second cell are arranged such that the positions in the column direction are staggered. In FIG. 4, the arrangement of each color filter in the color filter 25 is regarded as the arrangement of each color pixel in the pixel array 21 and the outer edge of each cell 20 is represented by a heavy line.

In the image sensor 10, four pixels constitute one cell 20 and the image sensor 10 outputs a signal for each cell 20. The image sensor 10 treats a plurality of pixels as one cell 20 and therefore can be expected to increase the saturated charge amount, improve the sensitivity, and reduce the random noise.

In the image sensor 10, an output circuit for each cell 20 is arranged for every four pixels in the column direction. In the image sensor 10, the circuits can be highly integrated in the column direction compared with the case where an output circuit is arranged for each of the pixels arranged in parallel in the column direction.

Furthermore, in the image sensor 10, circuits can be highly integrated not only in the column direction but also in the row direction by making the position of the cell 20 in the column direction different between columns adjacent to each other. The configuration of the solid-state imaging device 5 can be advantageous in terms of the layout by highly integrating circuits in the image sensor 10 both in the column direction and the row direction.

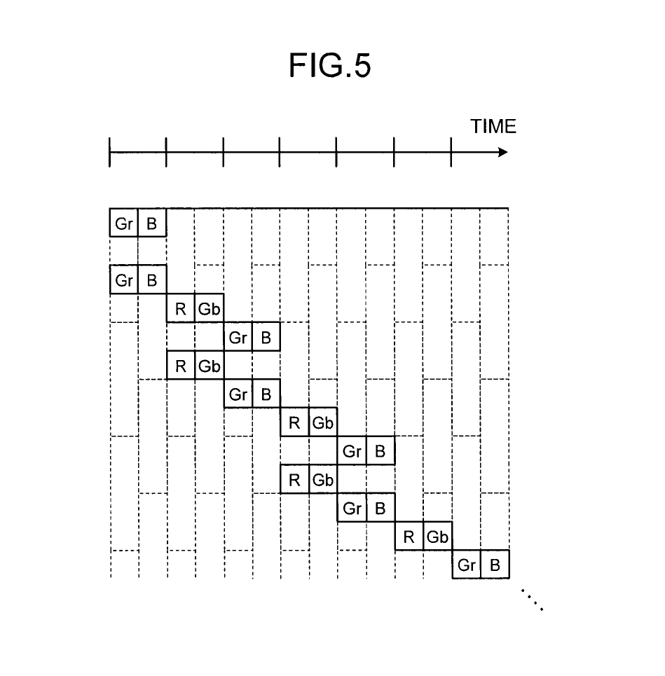

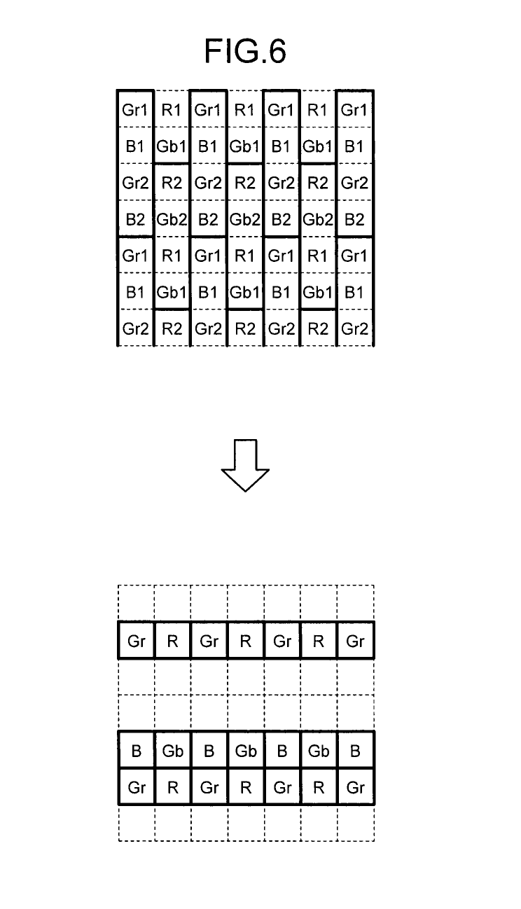

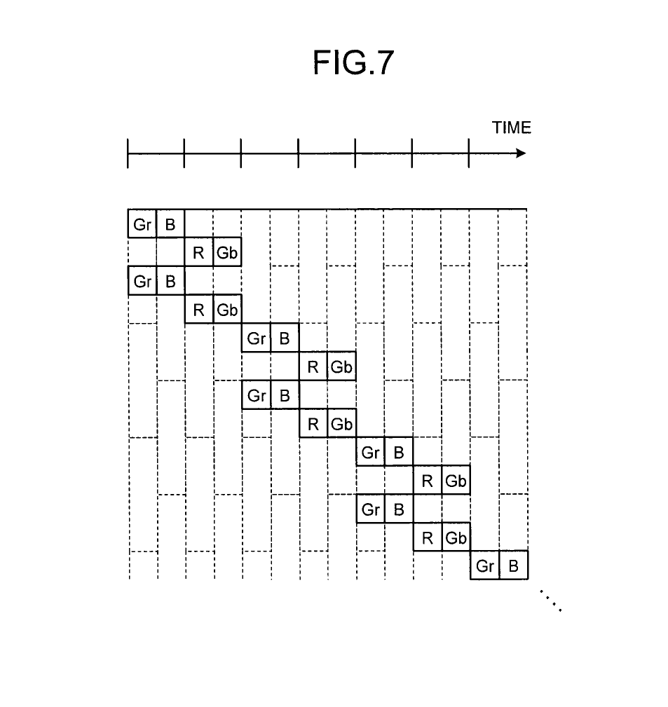

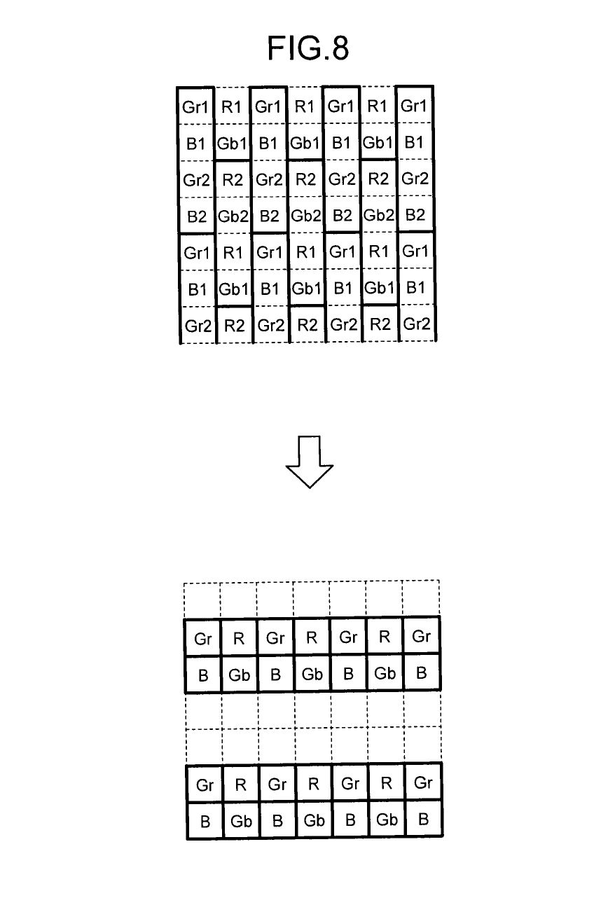

FIG. 5 is a diagram explaining the order of selecting a row, from which signal charge is read, by the vertical shift register in the binning process in the column direction. FIG. 6 is a diagram explaining a spatial arrangement of signal values obtained by the binning process when a row is selected in the order shown in FIG. 5. FIG. 7 is a diagram explaining the order of selecting a row in the binning process in a comparison example of the first embodiment. FIG. 8 is a diagram explaining a spatial arrangement of signal values obtained by the binning process when a row is selected in the order shown in FIG. 7.

The solid-state imaging device 5 can perform, for example, the binning process of reducing the number of pieces of data in the column direction to half. In the present embodiment, the binning process is a process of accumulating or interpolating charge from a plurality of pixels by one read operation and reading the charge.

The binning process in the case of the comparison example shown in FIG. 7 and FIG. 8 will be explained with reference to FIG. 4. L1, L2, L3, L4, L5, L6, L7, and L8 shown in FIG. 4 represent eight rows adjacent in the column direction.

The solid-state imaging device according to the comparison example selects L1 and L3 in the first operation and generates a signal value derived from signal charges Gr1 and Gr2 of two Gr pixels. The solid-state imaging device selects L2 and L4 in the second operation subsequent to the first operation and generates a signal vale derived from signal charges B1 and B2 of two B pixels.

The solid-state imaging device selects L3 and L5 in the third operation subsequent to the second operation and generates a signal value derived from signal charges R1 and R2 of two R pixels. The solid-state imaging device selects L4 and L6 in the fourth operation subsequent to the third operation and generates a signal vale derived from signal charges Gb1 and Gb2 of two Gb pixels.

The solid-state imaging device repeats such an operation also for L7 and subsequent rows. The signal value generated from charge of two pixels is regarded as being located intermediate the two pixels. With these operations, the solid-state imaging device can perform the binning process in the column direction transitioning from the state in the upper stage in FIG. 8 to the state in the lower stage in FIG. 8.

In all of the first to fourth operations, the solid-state imaging device according to the comparison example selects a row located adjacent to the row selected in the last operation as a row from which signal charge is read. Consequently, the solid-state imaging device sequentially select a row of each color component in accordance with the arrangement order of the color pixels.

When the above binning process is performed in a state where the positions of the cells 20 in the column direction are staggered every column, the solid-state imaging device according to the comparison example sums charge for two pixels in one cell 20 and outputs it for a Gr pixel and an R pixel. On the other hand, for a B pixel and a Gb pixel, the solid-state imaging device averages charge read from two cells 20 each for one pixel and outputs it. Whereas information on each cell 20 is obtained for a Gr pixel and an R pixel, only the information averaged for every two cells 20 is obtained for a B pixel and a Gb pixel.

The spectral sensitivity of the human eye has a peak around green located in an intermediate region in the visible wavelength region. Among RGB components, a G component greatly affects the noise and the perceived resolution. Therefore, because charge read from two cells 20 is averaged for at least one of a Gr pixel and a Gb pixel, the solid-state imaging device may cause deterioration of the SNR and reduction in the perceived resolution.

Next, the binning process according to the present embodiment shown in FIG. 5 and FIG. 6 will be explained with reference to FIG. 4. In the first operation, the vertical shift register 13 selects L1 and L3 in accordance with a timing signal from the timing control unit 15. The solid-state imaging device 5 generates a signal value derived from signal charges Gr1 and Gr2 of two Gr pixels by the selection of L1 and L3. In the first operation, the vertical shift register 13 selects rows so that Gr1 and Gr2 are read from one cell 20 at the same time.

In the second operation subsequent to the first operation, the vertical shift register 13 selects L2 and L4 in accordance with a timing signal from the timing control unit 15. The solid-state imaging device 5 generates a signal value derived from signal charges B1 and B2 of two B pixels by the selection of L2 and L4. In the second operation, the vertical shift register 13 selects rows so that B1 and B2 are read from two cells 20 at the same time.

In the third operation subsequent to the second operation, the vertical shift register 13 selects L5 and L7 in accordance with a timing signal from the timing control unit 15. The solid-state imaging device 5 generates a signal value derived from signal charges R1 and R2 of two R pixels by the selection of L5 and L7. In the third operation, the vertical shift register 13 selects rows located two rows away from the rows selected in the second operation as rows from which R1 and R2 are read. Consequently, the solid-state imaging device 5 reads R1 and R2 at the same time from two cells 20.

In the fourth operation subsequent to the third operation, the vertical shift register 13 selects L6 and L8 in accordance with a timing signal from the timing control unit 15. The solid-state imaging device 5 generates a signal value derived from signal charges Gb1 and Gb2 of two Gb pixels by the selection of L6 and L8. In the fourth operation, the vertical shift register 13 selects rows so that Gb1 and Gb2 are read at the same time from one cell 20.

The vertical shift register 13 repeats a row selection in a similar manner also for L8 and subsequent rows. In this manner, the vertical shift register 13 selects rows including green pixels at the same time for both of the first cell and the second cell. For a Gr pixel and a Gb pixel, the solid-state imaging device 5 sums charge for two pixels in one cell 20 and outputs it. On the other hand, for a B pixel and an R pixel, the solid-state imaging device 5 averages charge read from two cells 20 each for one pixel and outputs it.

For both a Gr pixel and a Gb pixel, the solid-state imaging device 5 can obtain information for each cell 20. The solid-state imaging device 5 can suppress deterioration of the SNR due to the binning process and reduction in the perceived resolution by obtaining information for each cell 20 for a G component that greatly affects the noise and the perceived resolution compared with other colors.

The solid-state imaging device 5 can, for example, switch between a binning mode in which the binning process is performed and a normal mode in which the binning process is not performed. When the binning mode is designated, the timing control unit 15 outputs a timing signal of selecting two rows at the same time in the order shown in FIG. 5 to the vertical shift register 13.

When the normal mode is designated, the timing control unit 15 outputs a timing signal of sequentially selecting each row of the pixel array 21 row by row from the top to the vertical shift register 13. In the normal mode, the vertical shift register 13 selects each row of the pixel array 21 row by row.

The solid-state imaging device 5 may be capable of switching between the binning mode and the normal mode, for example, in accordance with a user operation. When the solid-state imaging device 5 puts more emphasis on the speed of the image processing rather than the resolution of an image, the solid-state imaging device 5 may apply the binning mode, for example, for capturing moving images. When the solid-state imaging device 5 puts more emphasis on the resolution of an image rather than the speed of the image processing, the solid-state imaging device 5 may apply the normal mode, for example, for capturing still images. The solid-state imaging device 5 can perform imaging according to the request by switching between the binning mode and the normal mode.

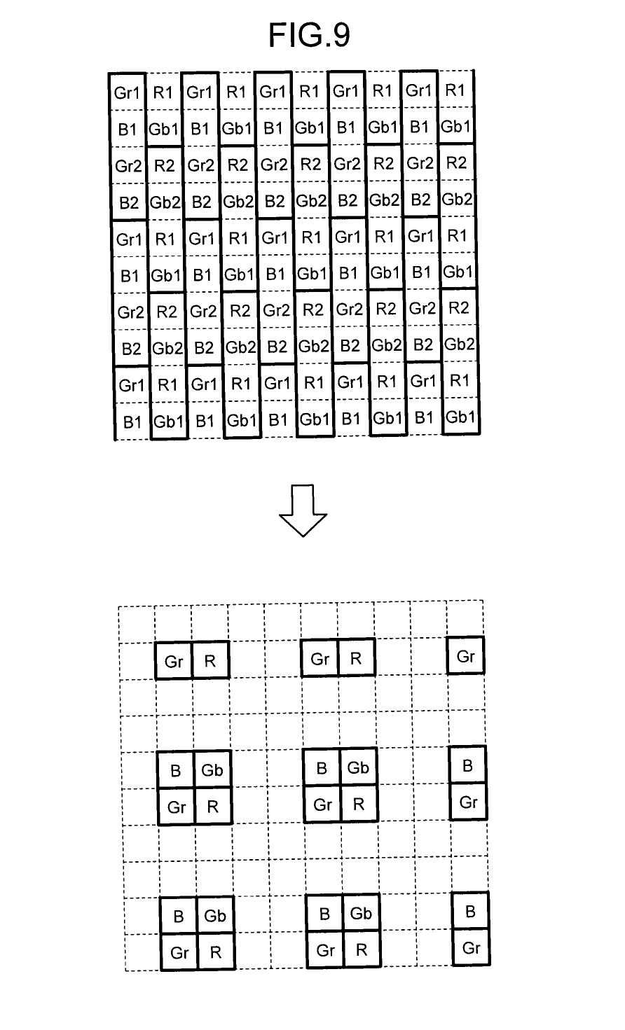

FIG. 9 is a diagram explaining the binning process by a solid-state imaging device according to the second embodiment. Components same as those in the first embodiment are denoted by the same reference numerals and overlapping explanation is appropriately omitted. The solid-state imaging device 5 according to the present embodiment has a configuration similar to that of the solid-state imaging device 5 in the first embodiment and furthermore can perform the binning process in the row direction.

The solid-state imaging device 5 according to the second embodiment can perform, for example, the binning process of reducing the number of pieces of data in the column direction and in the row direction to half. The vertical shift register 13 selects rows in a similar manner to the first embodiment. The vertical shift register 13 selects rows including green pixels at the same time for both of the first cell and the second cell in a similar manner to the first embodiment.

The horizontal shift register 14 reads signals of two pixels of the same color arranged in parallel in the row direction at the same time. The solid-state imaging device 5 averages signals read from two cells 20 arranged in parallel in the row direction and outputs it. With the binning process with respect to the column direction and the row direction, the solid-state imaging device 5 generates one signal value from signal values of pixels of the same color located at four corners of a 3×3 pixel block. The signal value generated from charge of four pixels is regarded as being located intermediate the block.

According to the second embodiment again, in a similar manner to the first embodiment, the configuration of the solid-state imaging device 5 can be advantageous in terms of the layout and the solid-state imaging device 5 can suppress deterioration of the SNR due to the binning process in the column direction and reduction in the perceived resolution. According to the second embodiment again, the solid-state imaging device 5 may be capable of switching between the binning mode and the normal mode. The solid-state imaging device 5 can perform imaging according to the request by switching between the binning mode and the normal mode.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A solid-state imaging device comprising:
a pixel array in which pixels are arranged in an array in a row direction and a column direction and which outputs a signal for each cell that includes a plurality of pixels arranged in parallel in the column direction;
a color filter that selectively causes colored light detected in a pixel to pass therethrough for each pixel; and
a row selection circuit that selects a row of a pixel from which signal charge is read in the pixel array, wherein
a red color filter that causes red light to pass therethrough, a green color filter that causes green light to pass therethrough, and a blue color filter that causes blue light to pass therethrough are arranged in the color filter,
cells are arranged such that positions in the column direction of a first cell including a blue pixel, which is a pixel corresponding to the blue color filter, and a green pixel, which is a pixel corresponding to the green color filter, and a second cell including a green pixel, which is a pixel corresponding to the green color filter, and a red pixel, which is a pixel corresponding to the red color filter, are staggered, and
in a binning process in the column direction, the row selection circuit selects rows including the green pixel in the first cell at a same time for the first cell and selects rows including the green pixel in the second cell at a same time for the second cell.

2. The solid-state imaging device according to claim 1, wherein the red color filter, the green color filter, and the blue color filter are arranged in a Bayer array.

3. The solid-state imaging device according to claim 1, wherein
the cell includes four pixels arranged in parallel in the column direction, and
the row selection circuit selects two rows including the green pixel at a same time in the binning process.

4. The solid-state imaging device according to claim 1, wherein in a normal mode other than a binning mode in which the binning process is performed, the row selection circuit selects each row in the pixel array row by row.

5. A camera module comprising:
an imaging optics that captures light from an object and forms an object image; and
a solid-state imaging device that captures the object image, wherein
the solid-state imaging device includes
a pixel array in which pixels are arranged in an array in a row direction and a column direction and which outputs a signal for each cell that includes a plurality of pixels arranged in parallel in the column direction,
a color filter that selectively causes colored light detected in a pixel to pass therethrough for each pixel, and
a row selection circuit that selects a row of a pixel from which signal charge is read in the pixel array,
a red color filter that causes red light to pass therethrough, a green color filter that causes green light to pass therethrough, and a blue color filter that causes blue light to pass therethrough are arranged in the color filter,
cells are arranged such that positions in the column direction of a first cell including a blue pixel, which is a pixel corresponding to the blue color filter, and a green pixel, which is a pixel corresponding to the green color filter, and a second cell including a green pixel, which is a pixel corresponding to the green color filter, and a red pixel, which is a pixel corresponding to the red color filter, are staggered, and
in a binning process in the column direction, the row selection circuit selects rows including the green pixel in the first cell at a same time for the first cell and selects rows including the green pixel in the second cell at a same time for the second cell.

6. The camera module according to claim 5, wherein the red color filter, the green color filter, and the blue color filter are arranged in a Bayer array.

7. The camera module according to claim 5, wherein
the cell includes four pixels arranged in parallel in the column direction, and
the row selection circuit selects two rows including the green pixel at a same time in the binning process.

8. The camera module according to claim 5, wherein in a normal mode other than a binning mode in which the binning process is performed, the row selection circuit selects each row in the pixel array row by row.

9. An imaging method comprising:
performing a row selection of selecting a row of a pixel from which signal charge is read in a pixel array in which pixels are arranged in an array in a row direction and a column direction; and
outputting the signal charge read from the pixel of the row selected by the row selection from the pixel array as a signal for each cell that includes a plurality of pixels arranged in parallel in the column direction, wherein
positions in the column direction of a first cell that is the cell including a blue pixel, which is a pixel corresponding to a blue color filter that causes blue light to pass therethrough, and a green pixel, which is a pixel corresponding to a green color filter that causes green light to pass therethrough, and a second cell that is the cell including a green pixel, which is a pixel corresponding to the green color filter, and a red pixel, which is a pixel corresponding to a red color filter that causes red light to pass therethrough, are staggered, and
in the row selection performed in a binning process in the column direction, rows including the green pixel in the first cell are selected at a same time for the first cell and rows including the green pixel in the second cell are selected at a same time for the second cell.

10. The imaging method according to claim 9, wherein the signal charge is read from the red pixel, the green pixel, and the blue pixel arranged in a Bayer array.

11. The imaging method according to claim 9, wherein
the row selection of selecting two rows including the green pixel at a same time is performed in the binning process, and
the cell including four pixels arranged in parallel in the column direction is set as a unit of output of the signal charge from the pixel array.

12. The imaging method according to claim 9, further comprising performing the row selection of selecting each row in the pixel array row by row in a normal mode other than a binning mode in which the binning process is performed.
